(19) United States
(12) Patent Application Publication
(10) Pub. No.: US 2023/0209727 A1
(43) Pub. Date: Jun. 29, 2023

(54) METHOD FOR MANUFACTURING CERAMIC ELECTRONIC COMPONENT

(71) Applicant: SAMSUNG ELECTRO-MECHANICS CO., LTD., Suwon-si (KR)

(72) Inventors: Chang Ho SEO, Suwon-si (KR); Sung Kwon AN, Suwon-si (KR)

(73) Assignee: SAMSUNG ELECTRO-MECHANICS CO., LTD., Suwon-si (KR)

(21) Appl. No.: 17/735,382

(22) Filed: May 3, 2022

(30) Foreign Application Priority Data
Dec. 29, 2021 (KR) 10-2021-0190537

(51) Int. Cl. H05K 3/46; H05K 1/03; H05K 3/00; H01L 23/15

(52) U.S. Cl. CPC H05K 3/4629; H01L 23/15; H05K 1/0306; H05K 3/0029

(57) ABSTRACT

A method for manufacturing a ceramic electronic component includes: forming a ceramic laminate by stacking ceramic green sheets on which internal electrode patterns are formed; obtaining an image of an upper portion of the ceramic laminate; determining cutting regions based on the image; and cutting the ceramic laminate by irradiating the cutting regions with a laser.

### CROSS-REFERENCE TO RELATED APPLICATION(S)

This application claims the benefit of priority to Korean Patent Application No. 10-2021-0190537 filed on Dec. 29, 2021 in the Korean Intellectual Property Office, the disclosure of which is incorporated herein by reference in its entirety.

### TECHNICAL FIELD

The present disclosure relates to a method for manufacturing a ceramic electronic component.

### BACKGROUND

Ceramic electronic components such as capacitors, inductors, piezoelectric elements, varistors, and thermistors include a ceramic body formed of a ceramic material, internal electrodes formed in the ceramic body, and external electrodes installed on surfaces of the ceramic body so as to be connected to the internal electrodes.

In accordance with a recent trend toward miniaturization of electronic products, ceramic electronic components used in various electronic products have also been required to have a small size and high capacitance. Such a ceramic electronic component is generally manufactured using a method for mixing a ceramic raw material with a solvent, a binder, and the like, to prepare a slurry, and then thinly applying the slurry to form a ceramic green sheet. Then, the ceramic green sheet is cut to a desired product size.

Currently, as a method for cutting the ceramic green sheet, a ceramic laminate, and the like, a cutting method using a stage and a blade has been widely used. In such a cutting method, a product to be cut is fixed to a vacuum stage, and cutting of the product is performed by moving the blade in a vertical direction of the vacuum stage.

However, in the cutting method using the blade, there have been various problems. First, when a ceramic laminate is formed by stacking and compressing the ceramic green sheets, a defect may occur due to deformation of the ceramic laminate. In the cutting method using the blade, the ceramic laminate needs to be cut in a straight line shape along the blade, and thus, deformation of the ceramic laminate may not be considered.

In addition, since the ceramic laminate and the blade are in direct contact with each other at the time of cutting the ceramic laminate, shear stress is applied to the ceramic laminate. A crack may be generated in a cut multilayer chip due to such shear stress. In addition, abrasion may occur in the blade due to a repeated cutting process. In this case, when the ceramic laminate is cut with a damaged blade, damage to a cut surface of the ceramic laminate may occur. Finally, individual multilayer chips separated after cutting the ceramic laminate come into contact with each other. Accordingly, a chip attachment defect may occur due to due to binders inside the multilayer chips or foreign materials at the time of cutting the ceramic laminate.

In order to solve such a problem, Patent Document 2 (Korean Patent Laid-Open Publication No. 10-2005-0036775) proposes a method for irradiating stacked green sheets with a laser at the time of manufacturing a multilayer electronic component, but still does not consider deformation of the ceramic laminate due to compression. In addition, in a laser cutting process according to the related art, separate reference marks have been inserted in order to set cutting lines, but there is a problem in which capacitance of a final product is decreased due to the separate reference marks.

### SUMMARY

An aspect of the present disclosure may provide a method for manufacturing a ceramic electronic component capable of solving a problem in which a cutting defect occurs due to deformation of a ceramic laminate.

An aspect of the present disclosure may also provide a method for manufacturing a ceramic electronic component capable of solving a problem in which a crack is generated in a multilayer chip due to shear stress generated at the time of cutting a ceramic laminate.

An aspect of the present disclosure may also provide a method for manufacturing a ceramic electronic component capable of solving a problem in which a chip attachment defect occurs due to contact between cut stacked chips.

An aspect of the present disclosure may also provide a method for manufacturing a ceramic electronic component capable of solving a problem in which capacitance of a ceramic electronic component decreases due to reference marks inserted into a ceramic laminate at the time of cutting the ceramic laminate with a laser.

However, an aspect of the present disclosure is not limited thereto, and may be more easily understood in a process of describing exemplary embodiments in the present disclosure.

According to an aspect of the present disclosure, a method for manufacturing a ceramic electronic component may include: forming a ceramic laminate by stacking ceramic green sheets on which a plurality of internal electrode patterns are formed; obtaining an image of an upper portion of the ceramic laminate; setting cutting regions through the image; and cutting the ceramic laminate by irradiating the cutting regions with a laser.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 is a schematic perspective view illustrating a ceramic laminate according to an exemplary embodiment in the present disclosure;

FIG. 2 is an exploded perspective view of the ceramic laminate;

FIG. 3 is a schematic view illustrating a method for manufacturing a ceramic electronic component according to an exemplary embodiment in the present disclosure;

FIG. 4 is a schematic view illustrating an image of an upper portion of a ceramic laminate;

FIG. 5 is an exploded perspective view of the ceramic laminate according to an exemplary embodiment in the present disclosure;

FIG. 6 is a schematic view illustrating the image of the upper portion of the ceramic laminate according to an exemplary embodiment in the present disclosure;

FIG. 7 is a schematic view illustrating the method for manufacturing a ceramic electronic component according to an exemplary embodiment in the present disclosure;

FIG. 8 is a perspective view illustrating a plurality of multilayer chips that are cut;

FIG. 9 is a cross-sectional view illustrating a cross-section of the multilayer chip in a first direction and a second direction;

FIG. 10 is a cross-sectional view illustrating a cross-section of the multilayer chip in a first direction and a third direction;

FIGS. 11 and 12 are schematic views illustrating a method for manufacturing a ceramic electronic component according to another exemplary embodiment in the present disclosure;

FIG. 13 is a schematic view illustrating an image of an upper portion of a ceramic laminate according to another exemplary embodiment in the present disclosure; and

FIG. 14 is an image of the multilayer chips captured with an optical microscope after the ceramic laminate is cut.

### DETAILED DESCRIPTION

In the drawings, a first direction may refer to a stacking direction or a thickness direction, a second direction may refer to a length direction, and a third direction may refer to a width direction.

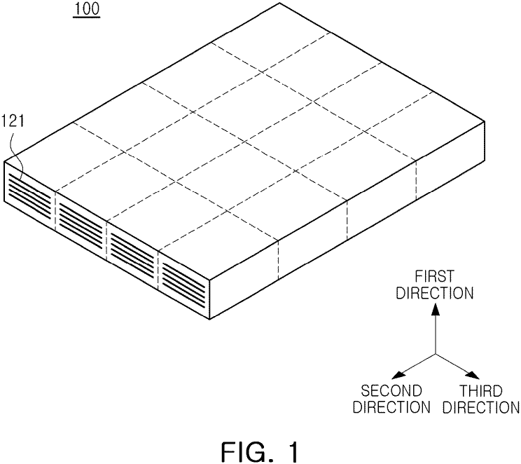

FIG. 1 is a schematic perspective view illustrating a ceramic laminate according to an exemplary embodiment in the present disclosure.

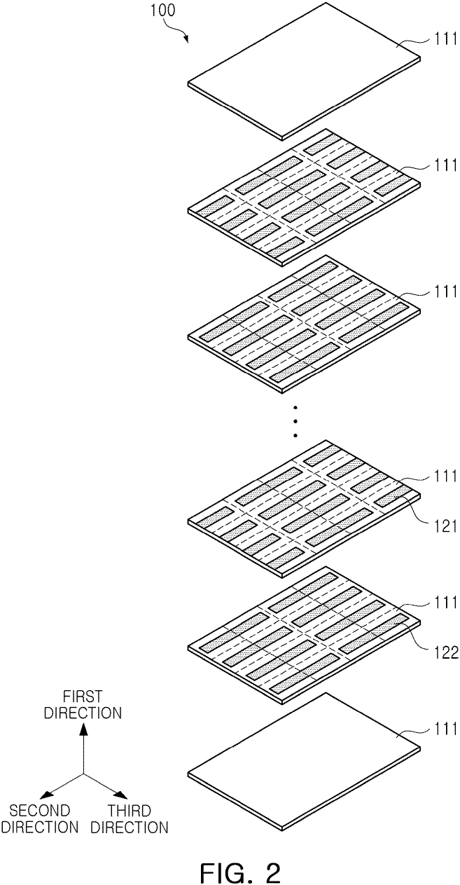

FIG. 2 is an exploded perspective view of the ceramic laminate.

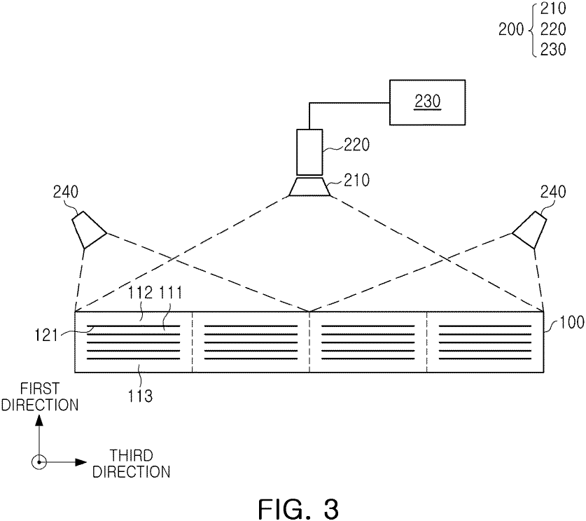

FIG. 3 is a schematic view illustrating a method for manufacturing a ceramic electronic component according to an exemplary embodiment in the present disclosure.

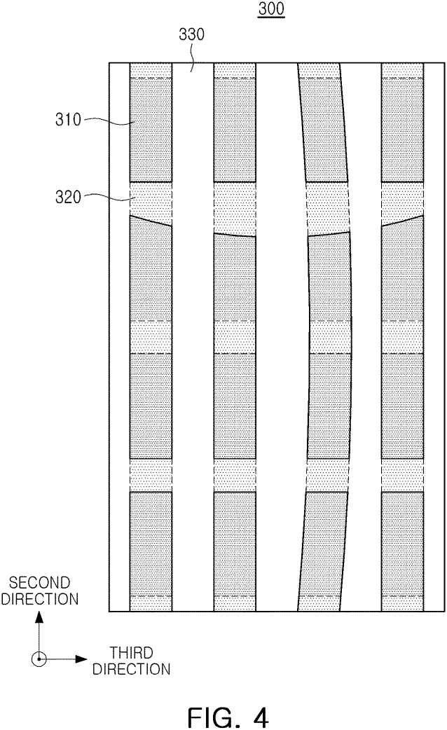

FIG. 4 is a schematic view illustrating an image of an upper portion of a ceramic laminate.

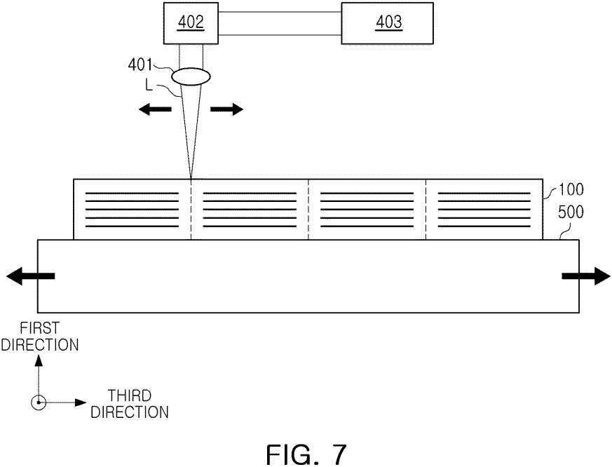

FIG. 7 is a schematic view illustrating a method for manufacturing a ceramic electronic component according to an exemplary embodiment in the present disclosure.

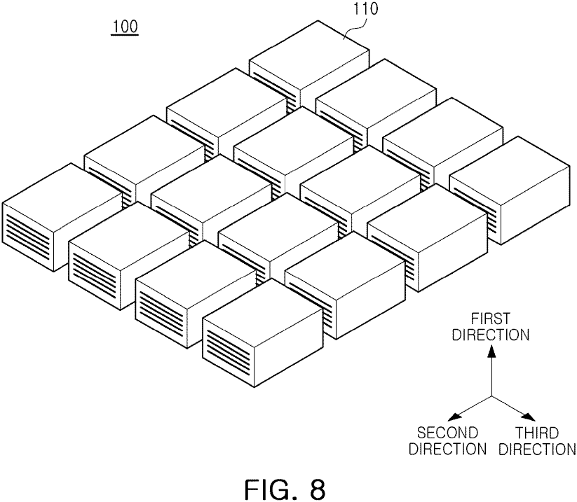

FIG. 8 is a perspective view illustrating a plurality of multilayer chips that are cut.

Referring to FIGS. 1 through 8, a method for manufacturing a ceramic electronic component according to an exemplary embodiment in the present disclosure may include forming a ceramic laminate 100 by stacking ceramic green sheets 111 on which a plurality of internal electrode patterns 121 and 122 are formed, obtaining an image 300 of an upper portion of the ceramic laminate 100, setting cutting regions through the image 300, and cutting the ceramic laminate 100 by irradiating the cutting regions with a laser.

As described above, when the ceramic laminate 100 is cut with a blade, the ceramic laminate 100 may not be cut in a curved line shape in consideration of deformation of the ceramic laminate, and the blade may be in direct contact with the ceramic laminate 100 at the time of cutting the ceramic laminate 100, and a crack may thus be generated in the ceramic laminate 100 due to shear stress.

On the other hand, in the method for manufacturing a ceramic electronic component according to an exemplary embodiment in the present disclosure, the ceramic laminate 100 may be cut by irradiating the cutting regions with the laser, and the ceramic laminate 100 may thus be cut in a curved line shape in consideration of the deformation of the ceramic laminate 100. In addition, the ceramic laminate 100 may be cut by a non-contact unit, and generation of a crack due to the shear stress may thus be prevented.

Hereinafter, respective steps included in the method for manufacturing a ceramic electronic component according to an exemplary embodiment in the present disclosure will be described in more detail.

First, the ceramic laminate 100 may be formed by stacking and compressing the ceramic green sheets 111 on which the plurality of internal electrode patterns 121 and 122 are formed. The ceramic green sheet 111 may be manufactured by mixing ceramic powder particles, a binder, a solvent, and the like, with each other to prepare a ceramic slurry and manufacturing the ceramic slurry in a sheet shape having a thickness of several micrometers by a doctor blade method. The ceramic powder particles are not particularly limited as long as a sufficient capacitance may be obtained. For example, barium titanate-based powder particles, lead composite perovskite-based powder particles, strontium titanate-based powder particles, or the like, may be used as the ceramic powder particles. The barium titanate-based powder particles may include BaTiO₃-based ceramic powder particles.

The internal electrode patterns 121 and 122 may be formed by printing a conductive paste for an internal electrode including a conductive metal at a predetermined thickness on the ceramic green sheets 111. A method for printing the conductive paste for an internal electrode is not particularly limited, and may be, for example, by a screen-printing method or a gravure printing method. In addition, the conductive paste for an internal electrode may include a conductive metal, common material powder particles, a dispersant, and a solvent, but the present disclosure is not limited thereto. The conductive metal may include one or more of nickel (Ni), copper (Cu), palladium (Pd), silver (Ag), gold (Au), platinum (Pt), tin (Sn), tungsten (W), titanium (Ti), and alloys thereof, and the present disclosure is not limited thereto.

In this case, the forming of the ceramic laminate may include alternately stacking first ceramic green sheets 111 on which a plurality of first internal electrode patterns 121 are formed and second ceramic green sheets 111 on which a plurality of second internal electrode patterns 122 are formed.

Next, the image 300 of the upper portion of the ceramic laminate 100 may be obtained. The image 300 of the upper portion of the ceramic laminate may be obtained by an image sensor 200, and the image sensor 200 may include a lens 210, a CCD 220, and an image processing unit 230. Here, the CCD 220 may refer to a charged coupled device (CCD), and may refer to a sensor converting light into an electrical signal to obtain an image.

More specifically, the obtaining of the image 300 of the upper portion of the ceramic laminate 100 may include making light incident on the upper portion of the ceramic laminate 100. The light may be irradiated from illumination units 240 disposed above the ceramic laminate 100. In this case, the light irradiated to the upper portion of the ceramic laminate 100 may be reflected, and a reflectivity for the light may be different between regions in which the internal electrode patterns 121 and 122 are formed and regions in which the internal electrode patterns 121 and 122 are not formed.

A wavelength of the light may be set within a range in which a difference in reflectivity between the regions in which the internal electrode patterns 121 and 122 are formed and the regions in which the internal electrode patterns 121 and 122 are not formed is substantially high, and may be set, for example, within a wavelength of a visible ray region, more specifically, within a range from 400 nm to 600 nm. However, the present disclosure is not limited thereto, and the wavelength of the light may be appropriately set according to compositions of the internal electrode patterns 121 and 122 and the ceramic green sheet 111. Since the conductive metal included in the internal electrode patterns 121 and 122 has a high absorption rate for the light having the wavelength within the above range, the reflectivity for the light irradiated to the upper portion of the ceramic laminate 100 may be higher in the regions in which the internal electrode patterns 121 and 122 are not formed than in the regions in which the internal electrode patterns 121 and 122 are formed.

The light reflected from the upper portion of the ceramic laminate 100 may be focused by the lens 210 of the image sensor 200, and the focused light may be input to the CCD 220 disposed above the lens 210. In this case, the input light may be converted into an electrical signal by the CCD 220. The image processing unit 230 may obtain the image 300 of the upper portion of the ceramic laminate 100 by receiving the electrical signal from the CCD 220 and converting the received electrical signal into an image. In this case, each region of the image 300 may have a different brightness depending on an amount of light reflected from the upper portion of the ceramic laminate 100. For example, a brightness may be high in a region having a high reflectivity and may be low in a region having a low reflectivity.

Next, the cutting regions are set based on the image 300 of the upper portion of the ceramic laminate 100 illustrated in FIG. 4. In this case, the setting of the cutting regions through the image 300 may include dividing the image into first regions 310 in which the first and second internal electrode patterns 121 and 122 overlap each other in the stacking direction and second regions 320 in which the first and second internal electrode patterns 121 and 122 do not overlap each other, and setting regions of the ceramic laminate 100 corresponding to the second regions 320 as the cutting regions. The first regions 310 and the second regions 320 may be divided by a difference in brightness in the image 300, and the brightness of the first regions 310 may be lower than that of the second regions 320.

In the first region 310, the first internal electrode pattern 121 and the second internal electrode pattern 122 overlap each other in the stacking direction, and a reflectivity for the light irradiated to the upper portion of the ceramic laminate 100 may thus be lower than in the first region 310 than in the second region 320. That is, the numbers of stacked internal electrode patterns 121 and 122 having a high absorption rate for the irradiated light may be more in the first region 310 than in the second region 320, and thus, a brightness in the image 300 may appear to be lower in the first region 310 than in the second region 320. To the contrary, the numbers of stacked internal electrode patterns 121 and 122 may be less in the second region 320 than in the first region 310, and thus, the brightness in the image 300 may appear to be higher in the second region 320 than in the first region 310. In this case, the regions of the ceramic laminate 100 corresponding to the second regions 320 in the image 300 may be set as the cutting regions.

In addition, the setting of the cutting regions through the image 300 may include dividing the image 300 into first regions 310, second regions 320, and third regions 330 in which the first and second internal electrode patterns 121 and 122 do not exist, and setting the second and third regions 320 and 330 as the cutting regions. The first regions 310, the second regions 320, and the third regions 330 may be divided by a difference in brightness in the image 300, the brightness of the first regions 310 may be lower than those of the second and third regions 320 and 330, and the brightness of the second regions 320 may be lower than that of the third regions 330.

The third regions 330 may be regions in which the internal electrode patterns 121 and 122 having a high absorption rate for the irradiated light do not exist, and may be regions having the highest reflectivity for the irradiated light. Accordingly, a brightness of the second regions 320 in which the first internal electrode patterns 121 or the second internal electrode patterns 122 are formed may be lower than that of the third regions 330. In this case, the regions of the ceramic laminate 100 corresponding to the second and third regions 320 and 330 in the image 300 may be set as the cutting regions.

As illustrated in FIG. 4, deformation of the internal electrode patterns 121 and 122 may occur in process of compressing the ceramic laminate 100. In the related art, the ceramic laminate 100 was cut with a blade, and accordingly, the cutting regions might not be set in consideration of deformation of the ceramic laminate 100. On the other hand, in the method for manufacturing a ceramic electronic component according to an exemplary embodiment in the present disclosure, a degree of the deformation of the ceramic laminate 100 due to the compression of the ceramic laminate 100 may be inspected through the image 300 of the upper portion of the ceramic laminate 100, and the cutting regions may be set as curve lines. In addition, by setting the cutting regions through the image 300 of the upper portion of the ceramic laminate 100, separate reference marks for cutting the ceramic laminate do not need to be inserted, and a decrease in capacitance of a final ceramic electronic component may thus be prevented.

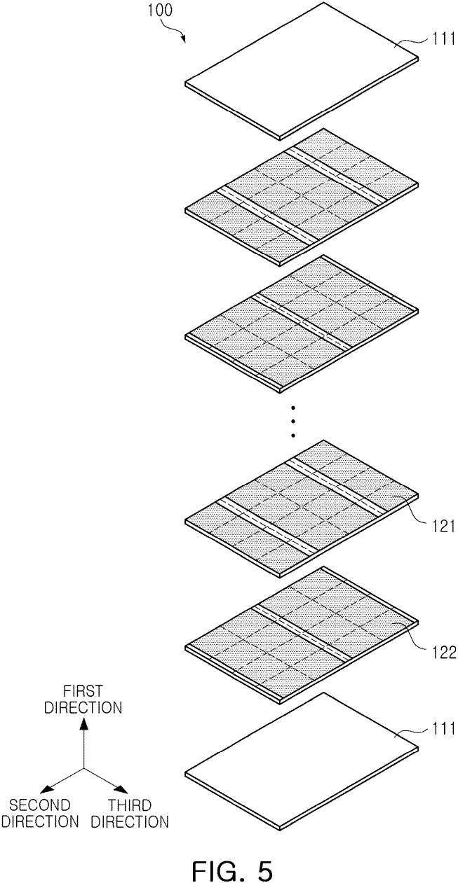

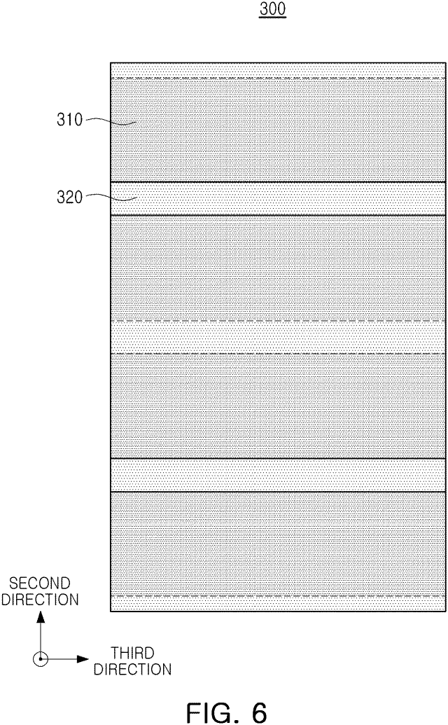

FIG. 5 is an exploded perspective view of the ceramic laminate according to an exemplary embodiment in the present disclosure. FIG. 6 is a schematic view illustrating the image of the upper portion of the ceramic laminate according to an exemplary embodiment in the present disclosure.

In an exemplary embodiment in the present disclosure, each of the first and second internal electrode patterns 121 and 122 may have a stripe shape. As illustrated in FIG. 5, a plurality of first internal electrode patterns 121 having a stripe shape may be formed at predetermined intervals on the first ceramic green sheet 111. In addition, a plurality of second internal electrode patterns 122 having a stripe shape may be formed on the second ceramic green sheet 111. In this case, the plurality of first internal electrode patterns 121 may be formed in parallel with each other, and the plurality of second internal electrode patterns 122 may be formed in parallel with each other.

Referring to FIG. 6, the image 300 of the upper portion of the ceramic laminate may be divided into the first regions 310 in which the first and second internal electrode patterns 121 and 122 overlap each other in the stacking direction and the second regions 320 in which the first and second internal electrode patterns 121 and 122 do not overlap each other. Each of the first regions 310 and the second regions 320 may also have a stripe shape due to the internal electrode patterns 121 and 122 having the stripe shape. In addition, the third regions 330 may not exist. In this case, the regions of the ceramic laminate 100 corresponding to the second regions 320 in the image 300 may be set as the cutting regions.

Next, referring to FIG. 7, the method for manufacturing a ceramic electronic component may include cutting the ceramic laminate 100 by irradiating the cutting regions with a laser. The laser L may be generated by a laser generator 403, and a scanner 402 may receive the generated laser. In this case, the scanner 402 may include a galvano scanner and/or an acoustic optical modulator (AOD), and may serve to irradiate the cutting regions set based on the image 300 with the laser. In this case, a focusing lens 401 may be disposed below the scanner 402 to focus the laser may be focused on the cutting region. The focusing lens 401 may be, for example, an F-theta lens, but the present disclosure is not limited thereto.

The ceramic laminate 100 may be disposed on a stage 500 and then cut by the laser, the stage 500 may move in the second and third directions for large-area machining of the ceramic laminate 100, and an irradiation point of the laser may be moved by the scanner 402.

Since the ceramic laminate 100 is cut through the laser, which is a non-contact cutting unit, the generation of cracks in a plurality of multilayer chips 110 that are separated may be prevented, and since a portion of the cutting region is removed by applying heat to the cutting region, a chip attachment defect and the like may be prevented.

In this case, a power density of the laser for cutting the ceramic laminate 100 may be in a range from 1 × 10⁷ W/cm² to 1 × 10¹⁴ W/cm², and when the power density of the laser exceeds 1 × 10¹⁴ W/cm², the separated multilayer chip 110 may be destroyed. In addition, a diameter of the laser focused by the focusing lens 401 may be in a range from 1 µm to 20 µm. The diameter of the laser may refer to a diameter of a laser focused on an upper surface of the ceramic laminate 100. When the diameter of the laser is less than 1 µm, a price of the focusing lens 401 may rise, and process stability may be deteriorated due to a severe change in machining line width. When the diameter of the laser is greater than 20 µm, a problem in which the internal electrode patterns 121 and 122 are exposed at the time of cutting the ceramic laminate may occur.

In this case, the first and second internal electrode patterns 121 and 122 may be alternately exposed to cut surfaces opposing each other by irradiating the cutting regions of the ceramic laminate 100 corresponding to the second regions 320 in the image 300 with the laser to cut the ceramic laminate 100. For example, in the cutting of the ceramic laminate 100 by irradiating the cutting regions with the laser, the laser may be irradiated along partial regions of the cutting regions, for example, centers of the cutting regions in the second direction. That is, the ceramic laminate 100 may be cut by irradiating points where lengths of the cutting regions in the second direction are half along the third direction with the laser. In this case, the ceramic laminate 100 may be cut by burning and removing the regions irradiated with the laser, and accordingly, the first and second internal electrode patterns 121 and 122 may be alternately exposed to cut surfaces opposing each other.

In addition, a plurality of multilayer chips 110 in component units may be formed by irradiating the cutting regions of the ceramic laminate 100 corresponding to the third regions 330 in the image 300 with the laser to cut the ceramic laminate 100. However, the cutting regions of the ceramic laminate 100 corresponding to the second regions 320 may be irradiated with the laser after the cutting regions of the ceramic laminate 100 corresponding to the third regions 330 are irradiated with the laser. Accordingly, the ceramic laminate 100 may be separated into the plurality of multilayer chips 110 in individual component units.

When the internal electrode patterns 121 and 122 have the stripe shape, the first and second internal electrode patterns 121 and 122 may be alternately exposed to the cut surfaces opposing each other by irradiating the cutting regions of the ceramic laminate 100 corresponding to the second regions 320 in the image 300 with the laser to cut the ceramic laminate 100. In addition, a plurality of multilayer chips 110 in component units may be formed by irradiating the laser along preset cutting lines parallel to the second direction to cut the ceramic laminate 100. In this case, the first and second internal electrode patterns 121 and 122 may be exposed to both side surfaces of the multilayer chip 110 opposing each other in the third direction. Since the internal electrode patterns 121 and 122 have the stripe shape, a method for setting the cutting lines parallel to the second direction is not particularly limited, and for example, a plurality of cutting lines positioned at equal intervals in the third direction may be set in consideration of a length of the multilayer chips 110 in the third direction, but the present disclosure is not limited thereto.

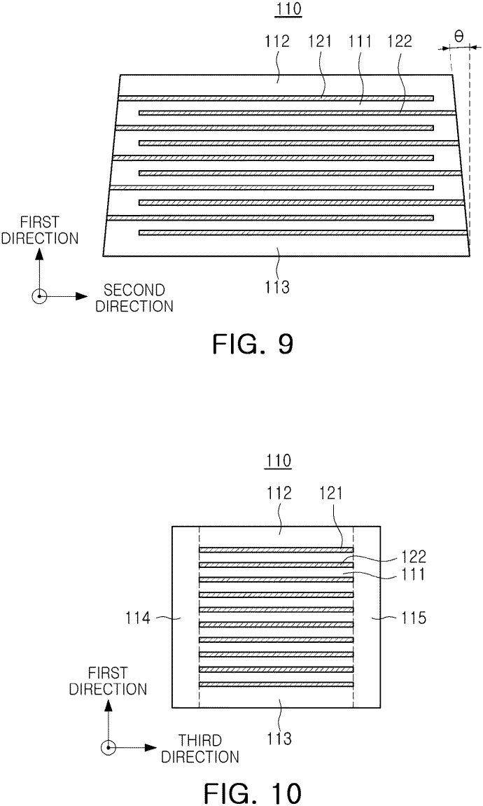

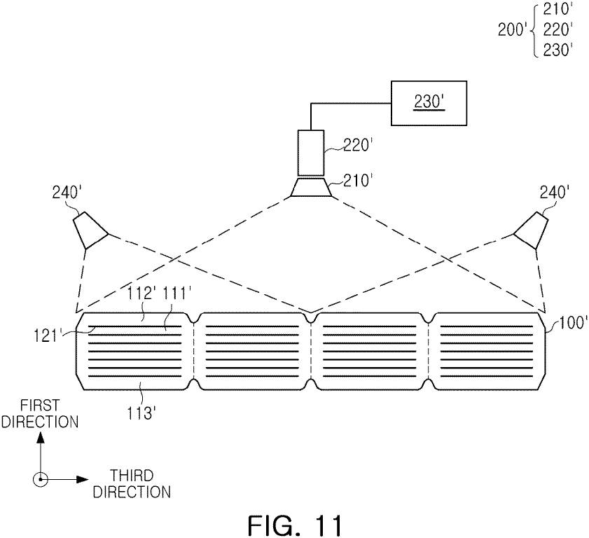

FIG. 9 is a cross-sectional view illustrating a cross-section of the multilayer chip in a first direction and a second direction. FIG. 10 is a cross-sectional view illustrating a cross-section of the multilayer chip in a first direction and a third direction.

In this case, when an angle formed between a cut surface of the ceramic laminate 100 and the stacking direction is a machining angle θ, the machining angle θ may be 3° or less. The laser L irradiated to the ceramic laminate 100 may have the smallest machining line width at a focal point, and may have a machining line width that increases as it becomes distant from the focal point. Accordingly, cross-sections of the cut multilayer chip 110 in the first direction and the second direction may have a trapezoidal shape. In this case, the machining angle θ may be adjusted to 3° or less in order to control a shape of the multilayer chip 110 in consideration of mounting characteristics of the ceramic electronic component. The machining angle θ may be controlled by adjusting the parameters of the focusing lens 401, the scanner 402, and the laser generator 403.

The multilayer chip 110 may include margin regions 114 and 115 disposed at distal ends of the plurality of internal electrode patterns 121 and 122 in the third direction. The margin regions 114 and 115 may be formed by irradiating the cutting region of the ceramic laminate 100 corresponding to the third region 330 of the image 300 with the laser. The margin regions 114 and 115 may serve to prevent damage to the internal electrode patterns 121 and 122 due to physical or chemical stress. According to the method for manufacturing a ceramic electronic component according to an exemplary embodiment in the present disclosure, a thickness of each of the margin regions 114 and 115 may be formed at a similar level by grasping a degree of the deformation of the ceramic laminate 100 and then cutting the ceramic laminate 100. Alternatively, the margin regions 114 and 115 may be formed by attaching separate ceramic greens sheet 111 when the internal electrode patterns 121 and 122 have the stripe shape.

Thereafter, the method for manufacturing a ceramic electronic component may further include sintering the plurality of multilayer chips 110. The internal electrode patterns 121 and 122 may become internal electrodes through the sintering, and the ceramic green sheets 111 may become dielectric layers through the sintering. In addition, the method for manufacturing a ceramic electronic component may further include forming external electrodes on outer surfaces of the sintered multilayer chip. Each of the external electrodes may include, for example, a conductive metal. The conductive metal may be, for example, one or more conductive metals of copper (Cu), nickel (Ni), tin (Sn), palladium (Pd), platinum (Pt), gold (Au), silver (Ag), tungsten (W), or titanium (Ti), lead (Pb), and alloys thereof, but is not limited thereto. The external electrodes may be formed by, for example, dipping the sintered multilayer chip in a conductive paste including a conductive metal. However, a method for forming the external electrodes is not limited thereto, and may be various methods such as a method of transferring a sheet onto the multilayer chip 110, an electroplating method, or a sputtering method. The plurality of multilayer chips 110 may become a plurality of ceramic electronic components through the processes described above.

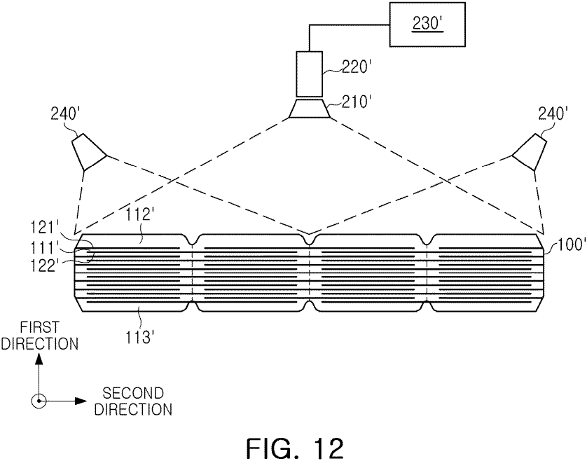

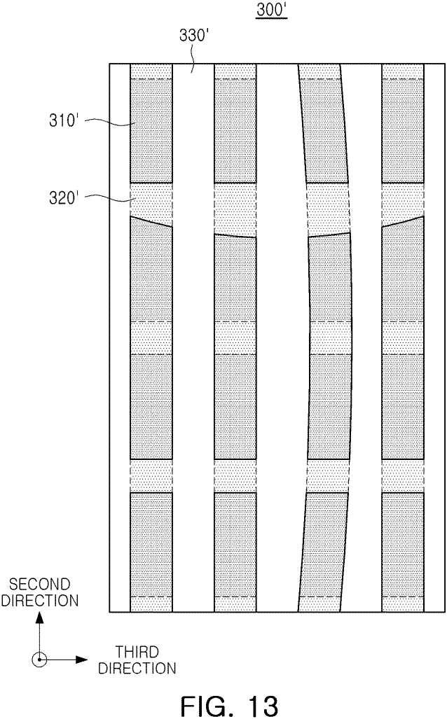

FIGS. 11 and 12 are schematic views illustrating a method for manufacturing a ceramic electronic component according to another exemplary embodiment in the present disclosure. FIG. 13 is a schematic view illustrating an image of an upper portion of a ceramic laminate according to another exemplary embodiment in the present disclosure.

In a case of a large ceramic electronic component in which a thickness of each of cover regions 112′ and 113′ exceeds 40 µm and is 300 µm or less, a difference in reflectivity between regions in which internal electrode patterns 121′ and 122′ are not formed and regions in which the internal electrode patterns 121′ and 122′ are formed may be decreased due to the large thickness of each of the cover regions 112′ and 113′, such that it may be difficult to distinguish these regions from each other on an image 300′.

Accordingly, the forming of the ceramic laminate 100′ may include compressing the ceramic laminate 100′ to depress at least partial regions of the ceramic laminate 100′ in the stacking direction. In a case of a large ceramic electronic component in which the number of stacked ceramic green sheets 111′ is large, a difference in thickness may occur between the regions in which the internal electrode patterns 121′ and 122′ are formed and the regions in which the internal electrode patterns 121′ and 122′ are not formed, and thus, the regions in which the internal electrode patterns 121′ and 122′ are not formed may be depressed by compressing the ceramic laminate 100′. In addition, regions in which the first and second internal electrode patterns 121′ and 122′ do not overlap each other in the stacking direction may have a smaller thickness than regions in which the first and second internal electrode patterns 121′ and 122′ overlap each other, and may thus be depressed at the time of compressing the ceramic laminate 100′.

Thereafter, as described above, the obtaining of the image of the upper portion of the ceramic laminate 100′ may include irradiating the upper portion of the ceramic laminate 100′ with the light through illumination units 240′, and the irradiated light may be scattered in the depressed regions. In addition, the scattered light may be converted into the image of the upper portion of the ceramic laminate 100′ by an image sensor 200′. In this case, the image sensor 200′ may include a dark field sensor. A clearer image 300′ may be obtained by obtaining the image 300′ only with the scattered light through the dark field sensor, but the present disclosure is not limited thereto.

As described above, the setting of the cutting regions through the image 300′ may include dividing the image 300′ into first regions 310′ in which the first and second internal electrode patterns 121′ and 122′ overlap each other in the stacking direction and second regions 320′ in which the first and second internal electrode patterns 121′ and 122′ do not overlap each other, and setting regions of the ceramic laminate 100′ corresponding to the second regions 320′ as the cutting regions.

For example, in the cutting of the ceramic laminate 100′ by irradiating the cutting regions with the laser, the laser may be irradiated along partial regions of the cutting regions, for example, centers of the cutting regions in the second direction. That is, the ceramic laminate 100′ may be cut by irradiating points where lengths of the cutting regions in the second direction are half along the third direction with the laser. In this case, the ceramic laminate 100′ may be cut by burning and removing the regions irradiated with the laser, and accordingly, the first and second internal electrode patterns 121′ and 122′ may be alternately exposed to cut surfaces opposing each other.

As described above, the setting of the cutting regions through the image 300′ of the upper portion of the ceramic laminate 100′ may include dividing the image 300′ into first regions 310′ in which the first and second internal electrode patterns 121′ and 122′ overlap each other in the stacking direction, second regions 320′ in which the first and second internal electrode patterns 121′ and 122′ do not overlap each other, and third regions in which the first and second internal electrode patterns 121′ and 122′ do not exist, and setting regions of the ceramic laminate 100′ corresponding to the second and third regions 320′ and 330′ as the cutting regions. In this case, the cutting regions may refer to the depressed regions of the ceramic laminate 100′ formed by the compression.

The first regions 310′ having the greatest thickness due to the stacking of the internal electrode patterns 121′ and 122′ may not be depressed, such that the light irradiated by the illumination units 240′ is not scattered in the first regions 310′. On the other hand, the third regions 330′ in which the first and second internal electrode patterns 121′ and 122′ do not exist may have the smaller thickness to be depressed, and a depression depth of the third regions 330′ may be greater than that of the second regions 320′, and a scattering rate of the irradiated light may be higher in the third regions 330′ than in the second regions 320′. Accordingly, the first regions 310′, the second regions 320′, and the third regions 330′ may be divided by a difference in brightness in the image 300′.

For example, when the image 300′ is obtained through the image sensor 200′, the third regions 330′ may have a higher brightness than the second regions 320′, and the second region 320′ may have a higher brightness than the first regions 310′. However, the present disclosure is not limited thereto, and the third regions 330′ may also have a lower brightness than the second regions 320′ and the second regions 320′ may also have a lower brightness than the first regions 310′, according to a setting condition of the image sensor 200′. In this case, the regions of the ceramic laminate 100′ corresponding to the second and third regions 320′ and 330′ in the image 300′ may be set as the cutting regions. Thereafter, the ceramic laminate 100′ may be cut by irradiating the cutting regions with the laser.

As described above, when the internal electrode patterns 121′ and 122′ have the stripe shape, the ceramic laminate 100 may be cut by irradiating the cutting regions of the ceramic laminate 100′ corresponding to the second regions 320′ in the image 300′ with the laser, and may be cut by irradiating the laser along preset cutting lines parallel to the second direction.

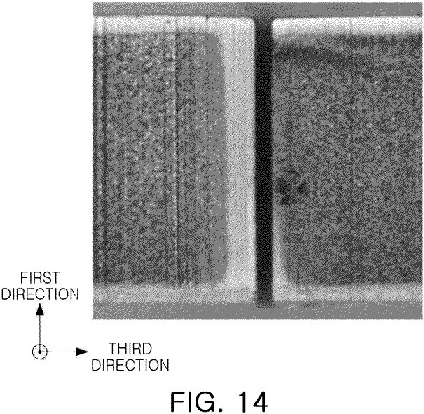

FIG. 14 is an image of the multilayer chips captured with an optical microscope after the ceramic laminate is cut. More specifically, FIG. 14 is an image of cut multilayer chips 110 captured by an optical microscope after a plurality of multilayer chips 110 are formed by irradiating upper regions of the ceramic laminate 100 corresponding to the second and third regions 320 and 330 with a laser. Through such an image, it may be confirmed that the margin regions 114 and 115 may be formed at a constant thickness and it may be confirmed that damage to surfaces of multilayer chips 110 due to cutting of the ceramic laminate 100 may be prevented.

As set forth above, according to an exemplary embodiment in the present disclosure, a cutting defect may be prevented by setting the cutting regions in consideration of the deformation of the ceramic laminate.

In addition, the generation of the crack in a multilayer chip due to shear stress generated at the time of cutting the ceramic laminate may be prevented.

Further, the occurrence of the chip attachment defect due to contact between cut stacked chips may be prevented.

Furthermore, a decrease in capacitance of a final due to the reference marks inserted into the ceramic laminate at the time of cutting the ceramic laminate with the laser may be prevented.

While exemplary embodiments have been shown and described above, it will be apparent to those skilled in the art that modifications and variations could be made without departing from the scope of the present invention as defined by the appended claims.

What is claimed is:

1. A method for manufacturing a ceramic electronic component, comprising:
forming a ceramic laminate by stacking ceramic green sheets on which internal electrode patterns are formed;
obtaining an image of an upper portion of the ceramic laminate;
determining cutting regions based on the image; and
cutting the ceramic laminate by irradiating the cutting regions with a laser.

2. The method of claim 1, wherein the forming of the ceramic laminate includes alternately stacking first ceramic green sheets on which first internal electrode patterns are formed and second ceramic green sheets on which second internal electrode patterns are formed.

3. The method of claim 2, wherein determining the cutting regions includes dividing the image into a first region in which the first and second internal electrode patterns overlap each other in a stacking direction of the ceramic green sheets and a second region in which the first and second internal electrode patterns do not overlap each other, and setting regions of the ceramic laminate corresponding to the second regions as the cutting regions.

4. The method of claim 3, wherein when a direction perpendicular to the stacking direction is a second direction, in the cutting of the ceramic laminate by irradiating the cutting regions with the laser, the laser is irradiated along centers of the cutting regions in the second direction.

5. The method of claim 3, wherein the internal electrode patterns have a stripe shape.

6. The method of claim 2, wherein determining the cutting regions includes dividing the image into a first region in which the first and second internal electrode patterns overlap each other in a stacking direction of the ceramic green sheets, a second region in which the first and second internal electrode patterns do not overlap each other, and a third region in which the first and second internal electrode patterns do not exist, and setting regions of the ceramic laminate corresponding to the second and third regions as the cutting regions.

7. The method of claim 1, wherein the ceramic laminate includes cover regions disposed at outermost portions of the plurality of internal electrode patterns in a stacking direction of the ceramic green sheets, and
a thickness of each of the cover regions is 40 µm or less.

8. The method of claim 1, wherein the laser is focused by a focusing lens, to a spot having a diameter in a range from 1 µm to 20 µm.

9. The method of claim 1, wherein a power density of the laser is in a range from 1 × 10⁷ W/cm² to 1 × 10¹⁴ W/cm².

10. The method of claim 1, wherein when an angle formed between a cut surface of the ceramic laminate and a stacking direction of the ceramic green sheets is a machining angle, the machining angle is 3° or less.

11. The method of claim 2, wherein forming of the ceramic laminate includes compressing the ceramic laminate to depress at least partial regions of the ceramic laminate in a stacking direction of the ceramic green sheets.

12. The method of claim 11, wherein determining the cutting regions includes dividing the image into first regions in which the first and second internal electrode patterns overlap each other in the stacking direction and second regions in which the first and second internal electrode patterns do not overlap each other, and setting regions of the ceramic laminate corresponding to the second regions as the cutting regions.

13. The method of claim 12, wherein when a direction perpendicular to the stacking direction is a second direction, in the cutting of the ceramic laminate by irradiating the cutting regions with the laser, the laser is irradiated along centers of the cutting regions in the second direction.

14. The method of claim 12, wherein the internal electrode patterns have a stripe shape.

15. The method of claim 11, wherein determining the cutting regions includes dividing the image into first regions in which the first and second internal electrode patterns overlap each other in the stacking direction, second regions in which the first and second internal electrode patterns do not overlap each other, and third regions in which the first and second internal electrode patterns do not exist, and setting regions of the ceramic laminate corresponding to the second and third regions as the cutting regions.

16. The method of claim 11, wherein the ceramic laminate includes cover regions disposed at outermost portions of the plurality of internal electrode patterns in the stacking direction, and
a thickness of each of the cover regions is in a range from 40 µm to 300 µm.

17. The method of claim 1, wherein obtaining the image of the upper portion of the ceramic laminate comprises irradiating a surface of the ceramic laminate with using a light source having a wavelength in a range from 400 nm to 600 nm, and obtaining the image of light reflected from the surface of the ceramic laminate.

18. The method of claim 2, wherein obtaining the image of the upper portion of the ceramic laminate comprises irradiating a surface of the ceramic laminate with light, the surface being parallel to the internal electrode patterns,
wherein a wavelength of the light is selected such that intensity of light reflected from the surface of the ceramic laminate is inversely proportional to a number of underlying internal electrode patterns.

19. The method of claim 17, wherein determining cutting regions comprises setting cutting regions based on intensity of the light reflected from the surface of the ceramic laminate.

20. The method of claim 1, wherein determining cutting regions comprises measuring brightness of different regions in the image, and setting cutting regions based on the measured brightness.

21. The method of claim 20, wherein obtaining the image comprises irradiating a surface of the ceramic laminate with light having a wavelength selected such that intensity of light reflected from the surface of the ceramic laminate is inversely proportional to a number of underlying internal electrode patterns, and
setting regions having relatively high brightness in the image as the cutting regions.
